(19) United States
(12) Patent Application Publication
(10) Pub. No.: US 2025/0380041 A1
(43) Pub. Date: Dec. 11, 2025

(54) IMAGE PICKUP APPARATUS

(71) Applicant: CANON KABUSHIKI KAISHA, Tokyo (JP)

(72) Inventors: RYOJI OKUNO, Kanagawa (JP); HONKAI TOMIMOTO, Tokyo (JP)

(21) Appl. No.: 19/188,314

(22) Filed: Apr. 24, 2025

(30) Foreign Application Priority Data
Jun. 11, 2024 (JP) 2024-094454

(51) Int. Cl. H04N 23/52; H04R 1/02; H05K 7/20

(52) U.S. Cl. CPC H04N 23/52; H04R 1/028; H05K 7/20145; H04R 2499/11

(57) ABSTRACT

An image pickup apparatus includes a sound pickup unit configured to pick up sound during moving image capturing, a fan, an elastic member provided in contact with the fan, and a first component that fixes the fan through the elastic member. The first component does not contact the sound pickup unit.

### BACKGROUND

### Technical Field

The present disclosure relates to an image pickup apparatus including a fan.

### Description of Related Art

In an image pickup apparatus including a fan, vibration of the fan propagates to a member to which the fan is attached, so that the vibration noise is amplified, and the drive noise and vibration noise of the fan are recorded by a microphone provided in the image pickup apparatus, which degrades recording quality. Japanese Patent Application Laid-Open No. 2000-232276 discloses a structure in which a plurality of support convex portions protruding from an antivibration fan cover enclosing the frame of a fan are press-fitted and supported by a casing and an attachment bracket to make it difficult for vibration noise due to fan drive to be transferred to the attachment bracket side.

In the structure disclosed in Japanese Patent Application Laid-Open No. 2000-232276, since the fan is pressed against the attachment bracket through the antivibration fan cover by press-fitting, vibration due to fan drive propagates to the attachment bracket. Furthermore, for reliable fixation, the antivibration fan cover needs to be press-fitted and supported not only in a direction along the rotational axis of the fan but also in a direction orthogonal to the rotational axis of the fan. That is, the antivibration fan cover is needed for all six surfaces of the frame, and the size of a device that houses the antivibration fan cover increases.

### SUMMARY

An image pickup apparatus according to one aspect of the disclosure includes a sound pickup unit configured to pick up sound during moving image capturing, a fan, an elastic member provided in contact with the fan, and a first component that fixes the fan through the elastic member. The first component does not contact the sound pickup unit.

Further features of various embodiments of the disclosure will become apparent from the following description of embodiments with reference to the attached drawings.

### BRIEF DESCRIPTION OF THE DRAWINGS

FIGS. 1A, 1B, and 1C are perspective views of a digital camera that is an example of an image pickup apparatus according to an embodiment of the present disclosure.

FIG. 2 is an exploded perspective view of a peripheral part of a top cover.

FIG. 3 illustrates the top cover when viewed from a-Y-axis direction.

FIG. 4 is a schematic diagram illustrating a section near a fan.

FIGS. 5A and 5B are detailed diagrams of components on an (air) intake side of the fan.

FIG. 6 is a cross-sectional view of the components on the intake side of the fan.

FIGS. 7A and 7B are detailed diagrams of components on an (air) exhaust side of the fan.

FIGS. 8A and 8B are cross-sectional views of the components on the exhaust side of the fan.

FIGS. 9A and 9B are detailed perspective views of a microphone sound pickup unit.

FIG. 10 is a block diagram illustrating the configuration of a digital camera.

### DETAILED DESCRIPTION

Referring now to the accompanying drawings, a detailed description will be given of embodiments according to the disclosure. Corresponding elements in respective figures will be designated by the same reference numerals, and a duplicate description thereof will be omitted.

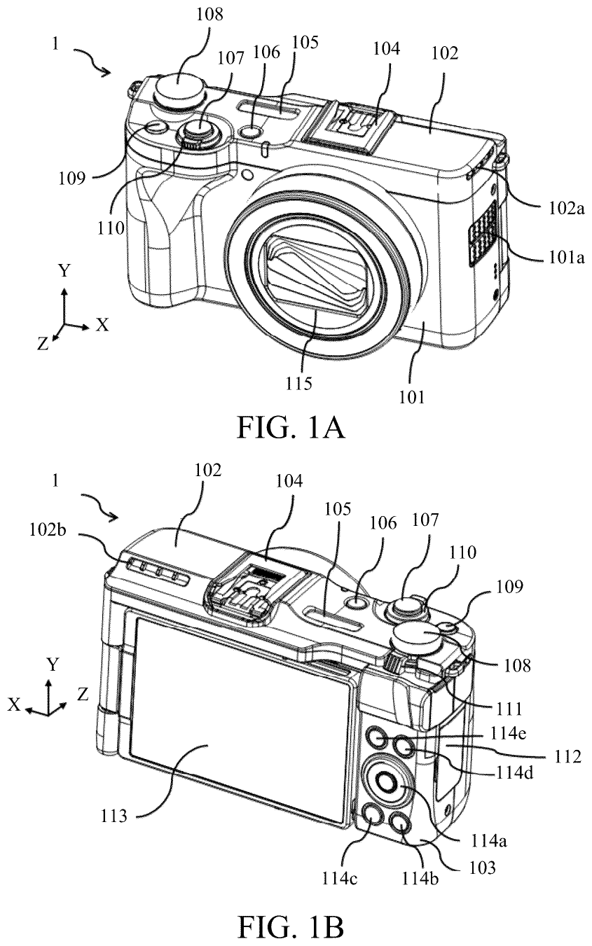

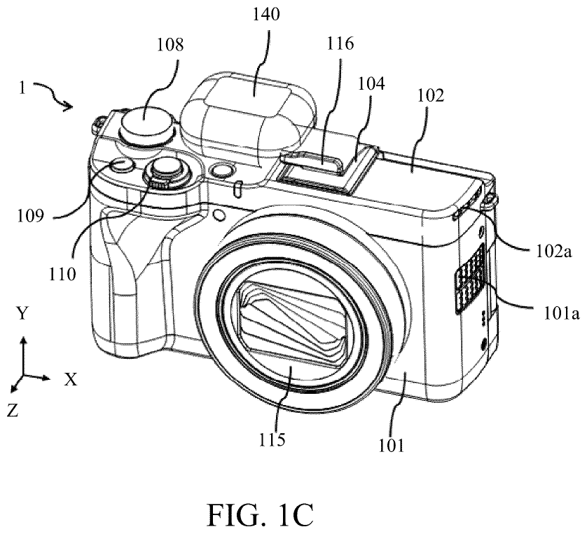

FIGS. 1A, 1B, and IC are perspective views of a digital camera 1 which is an example of an image pickup apparatus according to an embodiment of the present disclosure. FIG. 1A is a perspective view of the digital camera 1 when viewed from a front side (object side). FIG. 1B is a perspective view of the digital camera 1 when viewed from a rear side (image side). FIG. 1C is a perspective view of the digital camera 1 to which a windscreen (windbreak unit) 140 is attached. This embodiment illustrates a digital camera as an example of the image pickup apparatus, but is not limited to this example. In the present embodiment, a Z-axis is an axis parallel to the optical axis of the digital camera 1, a Y-axis extends in a height direction of the digital camera 1, and an X-axis extends in a width direction (lateral direction) of the digital camera 1.

The exterior of the digital camera 1 is formed by a front cover (second exterior member) 101, a top cover (first exterior member) 102, a rear cover 103, and a terminal cover 112 that covers an unillustrated external connection terminal in an openable manner.

A lens unit 115 is provided on the front side of the digital camera 1. The lens unit 115 may be integrated with the digital camera 1 or may be attachable to or detachable from the digital camera 1.

An accessory shoe 104, a microphone sound pickup unit (sound pickup unit) 105, a power button 106, a release button 107, a mode dial 108, a moving image capturing button 109, and a zoom lever 110 are provided at a top surface portion of the digital camera 1. The accessory shoe 104 is used to mount an external accessory. The microphone sound pickup unit 105 is constituted by a plurality of components as described later and picks up (collects) sound during moving image capturing.

A display unit 113 constituted by an LCD or the like is provided on the rear side of the digital camera 1. When the digital camera 1 is viewed from the rear side, a plurality of operation buttons 114a to 114e are provided on the right side of the display unit 113. Operating the operation buttons 114a to 114e can display a captured image on the display unit 113 and perform a variety of settings. A still-image/moving-image mode switching lever 111 configured to coaxially rotate with the mode dial 108 is provided.

A fan to be described later is mounted inside the digital camera 1. An intake port 101a for the fan is provided in the front cover 101. Exhaust ports 102a and 102b for the fan are provided in the top cover 102. The exhaust ports 102a and 102b are provided on a side opposite operation members such as the release button 107 and the zoom lever 110 with the accessory shoe 104 interposed in between. The exhaust port 102a is provided in a side surface of the digital camera 1, and the exhaust port 102b is provided in the back surface of the digital camera 1.

The fan, the accessory shoe 104, and the microphone sound pickup unit 105 are arranged on the upper surface of the digital camera 1 in a direction parallel to the X-axis direction of the digital camera 1 (direction orthogonal to the optical axis). The accessory shoe 104 is disposed between the fan and the microphone sound pickup unit 105. The fan is disposed in an area where the operation members are not disposed. The microphone sound pickup unit 105 is disposed in an area opposite to the fan with respect to the accessory shoe 104.

As the fan rotates, air flows into the interior of the digital camera 1 through the intake port 101a. Air having flowed into the interior of the digital camera 1 is exhausted from the exhaust ports 102a and 102b. The exhaust direction from the exhaust port 102a is a lateral direction (the +X-axis direction) opposite the microphone sound pickup unit 105 so that exhausted air does not strike the microphone sound pickup unit 105. The exhaust direction from the exhaust port 102b is a rearward direction of the digital camera 1 (the −Z-axis direction).

As illustrated in FIG. 1C, the digital camera 1 is configured to allow attachment of the windscreen 140 for reducing wind noise. The windscreen 140 is formed into a bag shape by folding and sewing a sheet such that synthetic hair attached to the sheet is positioned outside, and is attachable to an attachment portion 116. The windscreen 140 can be attached to the digital camera 1 by attaching the attachment portion 116 to the accessory shoe 104. The structure of the windscreen 140 is not limited to this example as long as its function is fulfilled. The windscreen 140 is disposed to cover an upper side of the microphone sound pickup unit 105.

The exhaust direction from the exhaust port 102a is a lateral direction (the +X-axis direction) opposite to the windscreen 140 so that exhausted air does not strike the windscreen 140. If air exhausted from the exhaust port 102a strikes the windscreen 140, wind noise is generated and recorded in moving image capturing. The windscreen 140 is disposed higher than the exhaust port 102a in the Y-axis direction so that air exhausted from the exhaust port 102a is unlikely to strike the windscreen 140.

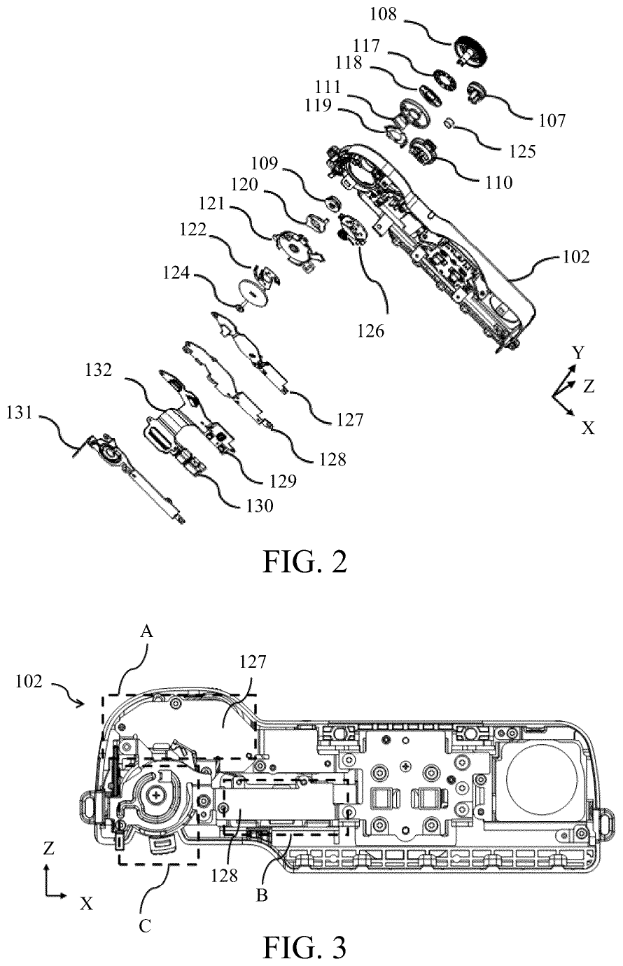

FIG. 2 is an exploded perspective view of a peripheral part of the top cover 102. FIG. 2 will omit some components for a simple description.

The mode dial 108 is rotationally operable and used to switch between imaging modes of the digital camera 1.

A click plate 117 is bonded to the mode dial 108 and integrally rotates with the mode dial 108, thereby generating a click feeling when the mode dial 108 is operated. More specifically, the click plate 117 has hole shapes in a number equal to the number of modes of the mode dial 108, and a click feeling is generated by an unillustrated click ball moving in and out of the hole shapes.

A click plate spring 118 has a plate spring shape to generate a click in the click plate 117 and presses the click ball against the click plate 117. The click plate spring 118 also presses the click ball against the still-image/moving-image mode switching lever 111. In other words, the click plate spring 118 is a component that generates clicks in the mode dial 108 and the still-image/moving-image mode switching lever 111.

The still-image/moving-image mode switching lever 111 is a two-position switching lever for switching between a still image mode and a moving image mode and coaxially rotates with the mode dial 108. A still-image/moving-image mode switching lever detection contact piece 119 detects the rotational position of the still-image/moving-image mode switching lever 111.

A spring 125 presses the release button 107 toward the outward direction. A zoom holder 126 holds the release button 107 and the zoom lever 110. The zoom holder 126 and the zoom lever 110 are welded by unillustrated thermal swaging and rotate integrally.

A rubber member 120 is a member that generates a click feeling in the moving image capturing button 109. The rubber member 120 is made of a rubber material and thus unlikely to generate operation noise when the moving image capturing button 109 is pressed down.

A mode dial holding member 121 holds the mode dial 108, the still-image/moving-image mode switching lever 111, and relevant components. A mode dial contact piece 122 detects the rotational position of the mode dial 108. The mode dial holding member 121 is fastened to the mode dial 108 by a screw 124 to integrally rotate. The mode dial contact piece 122 is fixed to the mode dial holding member 121 by a positioning boss. That is, the mode dial 108, the mode dial holding member 121, and the still-image/moving-image mode switching lever detection contact piece 119 integrally rotate.

A flexible printed circuit (FPC) 127 has switches for the release button 107, the zoom lever 110, and the moving image capturing button 109 mounted thereon, detects a variety of operations, and transmits signals corresponding to the detected operations.

A holding member 128 holds the release button 107, the zoom lever 110, the moving image capturing button 109, and relevant components.

A microphone element 129 that actually picks up audio information is mounted on an FPC 132. A microphone rubber 130 is assembled to cover the microphone element 129. In this manner, increasing airtightness makes it possible to enhance sound collection performance.

A holding member 131 holds the mode dial 108, the microphone element 129, and relevant components.

FIG. 3 illustrates the top cover 102 when viewed from the −Y-axis direction. FIG. 3 omits some components for a simple description.

Members to be operated during moving image capturing are the release button 107, the zoom lever 110, and the moving image capturing button 109. Operation noise to be picked up by the microphone sound pickup unit 105 may be reduced in a case where these operation members are operated during moving image capturing. The mode dial 108 is not a member operated during moving image capturing.

The release button 107 and the zoom lever 110 are positioned in a region A and held by the FPC 127. The microphone sound pickup unit 105 is positioned in a region B, and the mode dial 108 is positioned in a region C. The microphone sound pickup unit 105 and the mode dial 108 are held by the holding member 128. Separating a member (holding member 128) that holds the microphone sound pickup unit 105 and a member (FPC 127) that holds members operated during moving image capturing can restrain operation noise from being picked up by the microphone sound pickup unit 105.

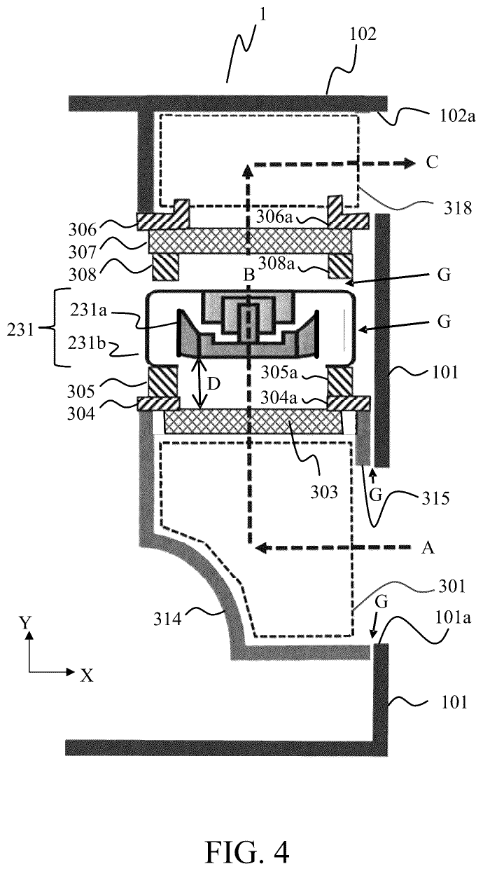

Referring now to FIG. 4, a schematic description will be given of an intake and exhaust structure of a fan 231 incorporated in the digital camera 1. FIG. 4 is a schematic diagram illustrating a section near the fan 231.

The fan 231 intakes air from a first air chamber 301, sends the air in a rotational axis direction B of the fan 231, and exhausts the air into a second air chamber 318. With respect to the fan 231, the first air chamber 301 side will be defined as an intake side, and the second air chamber 318 side will be defined as an exhaust side.

First, the intake-side structure of the fan 231 will be schematically described. The intake port 101a is opened through the front cover 101 in an intake direction A (−X-axis direction) to guide air outside the digital camera 1 to the fan 231. Air having entered into the digital camera 1 through the intake port 101a is guided to the first air chamber 301 surrounded by a heat sink 314, a duct 315, and a first wall portion 304.

The first wall portion 304 includes a flat portion in substantially parallel to the intake direction A and is constituted by a copper plate 311 and a heat-dissipating copper plate 312 to be described later. An opening portion 304a for guiding air in the first air chamber 301 to the fan 231 is formed in the first wall portion 304. A ventilation sheet 303 is bonded to the flat portion of the first wall portion 304 around the opening portion 304a on the first air chamber 301 side. The ventilation sheet 303 is made of a material such as a mesh sheet and configured to allow air to pass through while preventing foreign matters such as sand larger than a particular size from passing through.

The fan 231 includes a movable portion 231a that is a rotational blade portion, and a fixed portion 231b including a fan frame rotatably supporting the movable portion 231a, a mounting substrate, and the like. The fixed portion 231b is bonded on the fan 231 side of the first wall portion 304 through an elastic member 305 such that the rotational axis direction B is substantially orthogonal to the intake direction A. The fixed portion 231b has a plurality of surfaces, but only one of the surfaces through which an opening portion 305a to be described later is formed contacts the elastic member 305, whereas the other surfaces do not contact other members. An adhesive portion such as a double-sided adhesive tape is provided on both surfaces on the fan 231 side and the first wall portion 304 side of the elastic member 305. The material of the elastic member 305 may be a foamed resin, rubber, or the like that attenuates drive vibration of the fan 231, but this embodiment is not limited to this example. The elastic member 305 has the opening portion 305a. The opening portion 305a serves as a vent for guiding air in the first air chamber 301 to the fan 231. The opening portion 305a is positioned in a surface opposite to the movable portion 231a, and accordingly, the movable portion 231a does not contact the elastic member 305.

Since the fan 231 is bonded to the first wall portion 304 through the elastic member 305 having a certain thickness, a gap D is formed between the movable portion 231a and the surface of the ventilation sheet 303. Since the ventilation sheet 303 provided in a ventilation path (flow path) can be separated from the movable portion 231a by the gap D, it is possible to restrain the movable portion 231a from contacting the ventilation sheet 303 during driving, which could otherwise stop driving the fan 231 or generate abnormal noise.

This embodiment provides the ventilation sheet 303 as a measure to prevent foreign matters such as sand from entering the fan 231, but the ventilation sheet 303 may not be provided to the digital camera 1 that is not used in environments where foreign matters enter.

In this embodiment, the fan 231 is fixed to the digital camera 1 only on the intake side of the fan 231 to the first wall portion 304 through the elastic member 305. The fan 231 is supported in a floating manner on the first wall portion 304 by the elastic member 305 without being pressed against the first wall portion 304 that fixes the fan 231. Vibration energy of the fan 231 generated during driving is attenuated by micro vibration of the fan 231, which is supported in the floating manner on the elastic member 305, and thus vibration of the fan 231 is less likely to be directly propagated to the first wall portion 304. Moreover, the size of the internal structure of the digital camera 1 can be reduced because only an end surface of the elastic member 305 on the intake side of the fan 231 is fixed, the elastic member 305 and any component supporting the elastic member 305 do not need to be disposed on the other end surfaces in five directions of the fan 231 except for the end surface on the intake side.

The fan 231 has a gap G with components other than the elastic member 305 bonded by the double-sided adhesive tape, and is not in contact with them. Furthermore, components constituting the first wall portion 304 to which the fan 231 is fixed, the heat sink 314, and the duct 315 have the gap G with the front cover 101 and are not in contact with it.

Next follows a schematic description of the exhaust-side structure of the fan 231. The exhaust port 102a is opened in the top cover 102 in an exhaust direction C (+X-axis direction) to exhaust air from the fan 231 in the digital camera 1 to the outside of the digital camera 1. As illustrated in FIG. 1B, the exhaust port 102b provided in the rearward direction of the digital camera 1 is opened from front to back of the paper plane. The rotational axis direction B and the exhaust direction C are approximately orthogonal to each other.

Air exhausted from the fan 231 is guided to the second air chamber 318 surrounded by a second wall portion 306 and the top cover 102. The second wall portion 306 includes a flat portion that is approximately parallel to the exhaust direction C and has an opening portion 306a. The opening portion 306a serves as a vent for guiding air exhausted from the fan 231 into the second air chamber 318. A ventilation sheet 307 is bonded around the opening portion 306a on the fan 231 side of the second wall portion 306. The ventilation sheet 307 is configured to allow air to pass through it while preventing foreign matters such as sand larger than a particular size from passing through it to the fan 231 side. An elastic member 308 having an opening portion 308a is bonded on the fan 231 side of the ventilation sheet 307 by using adhesive such as a double-sided adhesive tape. The elastic member 308 is made of a foamed resin or the like. The elastic member 308 has a shape in which the elastic member 308 is brought as close as possible to the fan 231 so as to prevent air exhausted from the fan 231 from leaking to the interior of the digital camera 1, and guides air exhausted from the fan 231 to the second air chamber 318 through the opening portion 308a.

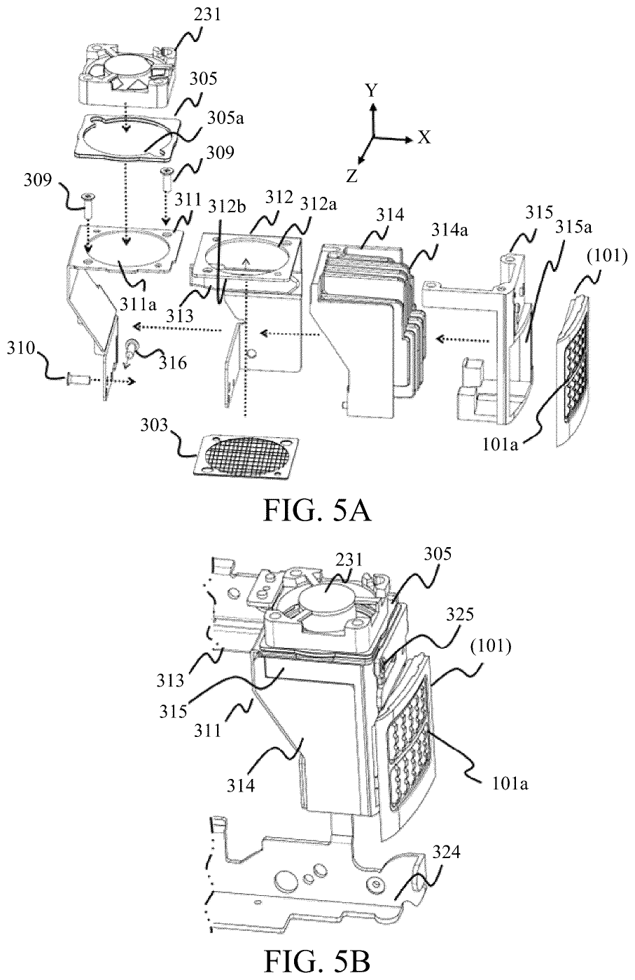

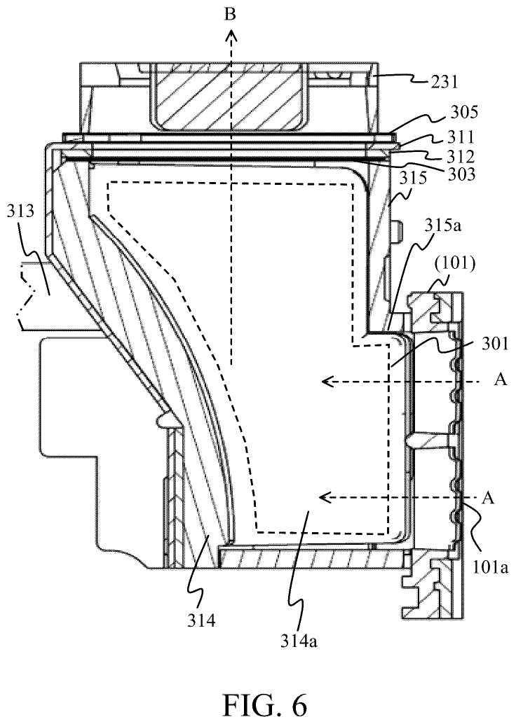

The intake-side component configuration of the fan 231 will be described below in detail with reference to FIGS. 5A, 5B, and 6. FIGS. 5A and 5B are detailed diagrams of intake-side components of the fan 231. FIG. 6 is a cross-sectional view of the intake-side components of the fan 231.

FIG. 5A is an exploded view of the intake-side components of the fan 231. The duct 315 is disposed at a position facing the intake port 101a provided in the front cover 101 (partially illustrated). The duct 315 is made of resin and fitted into the heat sink 314 made of aluminum. The duct 315 has an opening portion 315a toward a side where the intake port 101a is provided. The duct 315 can intake air from the outside of the digital camera 1 through the opening portion 315a. The heat sink 314 includes a plurality of protrusion portions 314a. The plurality of protrusion portions 314a are installed in accordance with the positions of louvers of the intake port 101a. The protrusion portions 314a function as a rectifying plate that increases the contact area with air taken in through the intake port 101a and forms airflow to the fan 231.

For example, a heat pipe or a graphite sheet is used as a heat conduction component 313. This embodiment uses a heat pipe as the heat conduction component 313. The heat conduction component 313 is soldered to the heat-dissipating copper plate 312 and transfers heat generated in a system controller (control unit) 209, an image sensor (imaging unit) 203, and an image processing unit 211 to be described later, and the like to the heat sink 314 through the heat-dissipating copper plate 312. The heat-dissipating copper plate 312 has an opening portion 312a. The heat-dissipating copper plate 312 guides air from the intake port 101a to the fan 231 side through the opening portion 312a. A flat portion around the opening portion 312a constitutes the first wall portion 304. The ventilation sheet 303 is bonded to a ventilation sheet bonding portion 312b of the heat-dissipating copper plate 312 from the −Y-axis direction. A flat portion of the heat-dissipating copper plate 312, which faces the ventilation sheet 303 around the opening portion 312a, is the ventilation sheet bonding portion 312b. Since the ventilation sheet bonding portion 312b is flat, the ventilation sheet 303 may be configured as a sheet component. The ventilation sheet 303 can be produced through simple processes of laminating sheet materials such as a mesh sheet and a double-sided adhesive tape and then punching out the outer shape.

The copper plate 311 has an opening portion 311a on its upper surface and guides air from the intake port 101a to the fan 231 side. The copper plate 311 is assembled to overlap the heat-dissipating copper plate 312 from the −Y-axis direction such that the opening portions 311a and 312a align with each other. The copper plate 311 transfers heat generated by the system controller 209, the image sensor 203, the image processing unit 211, and the like to the heat sink 314 by using an unillustrated heat conduction component made of a graphite sheet or the like. A flat peripheral part of the opening portion 311a constitutes the first wall portion 304. The fan 231 is adhered to the peripheral part of the opening portion 311a from the +Y-axis direction through the elastic member 305. Since the copper plate 311 around the opening portion 311a is flat, bonding work of the sheet-shaped elastic member 305 can be easily performed. The heat-dissipating copper plate 312 closely contacts the heat sink 314 and transfers heat to the heat sink 314. A heat conduction rubber or the like may be interposed between the copper plate 311, the heat-dissipating copper plate 312, and the heat sink 314 to increase adhesion, thereby improving heat transfer.

The duct 315 and the copper plate 311 are fixed by a screw 310 from the −X-axis direction via the heat sink 314 and the heat-dissipating copper plate 312. Further, the duct 315 and the copper plate 311 are fixed by a screw 309 from the +Y-axis direction via the heat-dissipating copper plate 312. Furthermore, the duct 315 and the heat-dissipating copper plate 312 are fixed by a screw 316 from the −Z-axis direction via the heat sink 314.

FIG. 5B is a perspective view of a state in which components described above with reference to FIG. 4A are assembled. The copper plate 311 to which the fan 231 is fixed, the heat-dissipating copper plate 312 to which the copper plate 311 is fixed, the heat sink 314, and the duct 315 are not exterior components of the digital camera 1 but are fixed to a chassis 324 inside the digital camera by a screw 325.

As illustrated in FIG. 6, space surrounded by the duct 315, the heat sink 314, the heat-dissipating copper plate 312, and the copper plate 311 serves as the first air chamber 301. The flat portion of the copper plate 311 where the opening portion 311a is formed and the flat portion of the heat-dissipating copper plate 312 where the opening portion 312a is formed serve as the first wall portion 304 extending approximately in parallel to the intake direction A. The fan 231 is separated from the first air chamber 301 by the first wall portion 304 constituted by the heat-dissipating copper plate 312 and the copper plate 311. The intake side of the fan 231 is covered with the ventilation sheet 303.

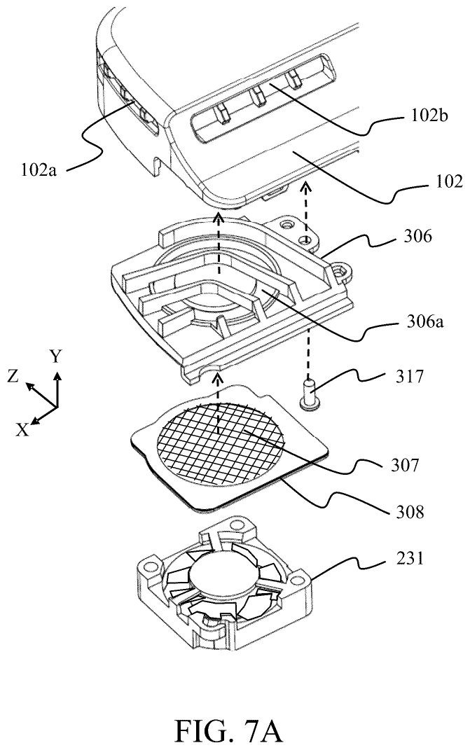

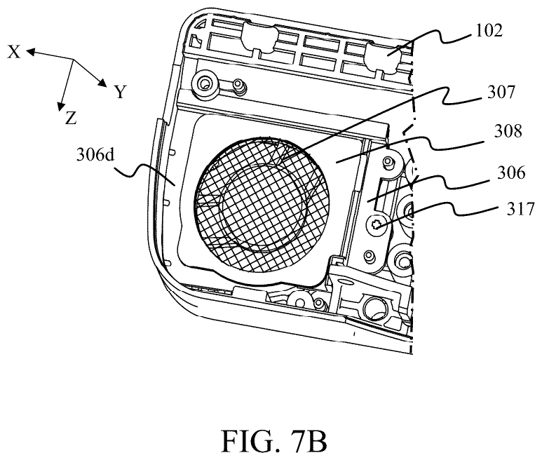

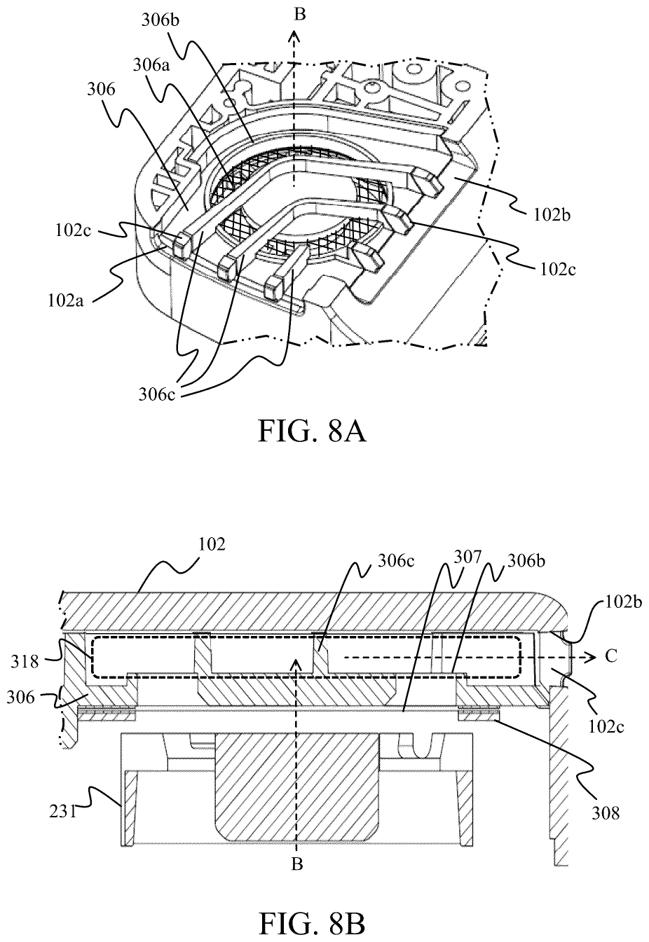

The exhaust-side component configuration of the fan 231 will be described below in detail with reference to FIGS. 7A to 8B. FIGS. 7A and 7B are detailed diagrams of exhaust-side components of the fan 231. FIGS. 8A and 8B are cross-sectional views of the exhaust-side components of the fan 231.

FIG. 7A is an exploded perspective view of the exhaust-side components of the fan 231 when viewed from the +Y-axis direction. The elastic member 308 is bonded to the ventilation sheet 307 by a double-sided adhesive tape or the like. The ventilation sheet 307 is bonded to the second wall portion 306 from the +Y-axis direction by a double-sided adhesive tape or the like. The second wall portion 306 is fastened to the top cover 102 by a screw 317.

FIG. 7B is a perspective view of a state in which components described above with reference to FIG. 7A are assembled, when viewed from the −Y-axis direction. The flat portion of the second wall portion 306 where the opening portion 306a (illustrated in FIG. 7A) facing the ventilation sheet 307 is formed is a ventilation sheet bonding portion 306d. The ventilation sheet bonding portion 306d can easily ensure a bonding area on a wide flat surface with small unevenness around the opening portion 306a and thus enhance adhesion to the ventilation sheet 307. Moreover, since the ventilation sheet bonding portion 306d is a flat surface with small unevenness, bonding work of the ventilation sheet 307 in a flat plate shape can be easily performed. The ventilation sheet 307 and the elastic member 308 can be produced through simple processes of bonding sheet materials such as a mesh sheet, a double-sided adhesive tape, and an elastic foam sheet and then punching out the outer shape.

FIG. 8A is a cross-sectional view of the exhaust-side components of the fan 231 taken along a plane perpendicular to the rotational axis direction B. A rib 306b extending in the rotational axis direction B is provided at the entire circumference of an end part of the opening portion 306a of the second wall portion 306. The rib 306b is provided to prevent foreign matters, such as sand entering from the exhaust ports 102a and 102b, from directly entering the fan 231 side through the opening portion 306a. In addition, a plurality of protrusion portions 306c protruding in the rotational axis direction B are provided over the flat portion of the second wall portion 306 and the opening portion 306a. End parts on the exhaust port 102a side and the exhaust port 102b side of the protrusion portions 306c match the positions of louvers 102c. Some of the protrusion portions 306c have a shape connecting the exhaust ports 102a and 102b in a smooth arc. Thereby, foreign matters having entered from one of the exhaust ports can easily slide along the arc shape and be exhausted from the other exhaust port, and thus are unlikely to stay in the second air chamber 318. The protrusion portions 306c also function as a rectifying plate that guides air exhausted from the fan 231 to the two exhaust ports 102a and 102b.

FIG. 8B is a cross-sectional view of the exhaust-side components of the fan 231 taken along a plane parallel to the rotational axis direction B. Space surrounded by the second wall portion 306 and the top cover 102 serves as the second air chamber 318. As illustrated in FIGS. 7A and 7B, the second wall portion 306 includes, around the opening portion 306a, a flat portion extending approximately in parallel to the exhaust direction C. The fan 231 is separated from the second air chamber 318 by the ventilation sheet 307 adhered to the second wall portion 306 and the flat portion of the second wall portion 306, and has its exhaust side covered with the ventilation sheet 307.

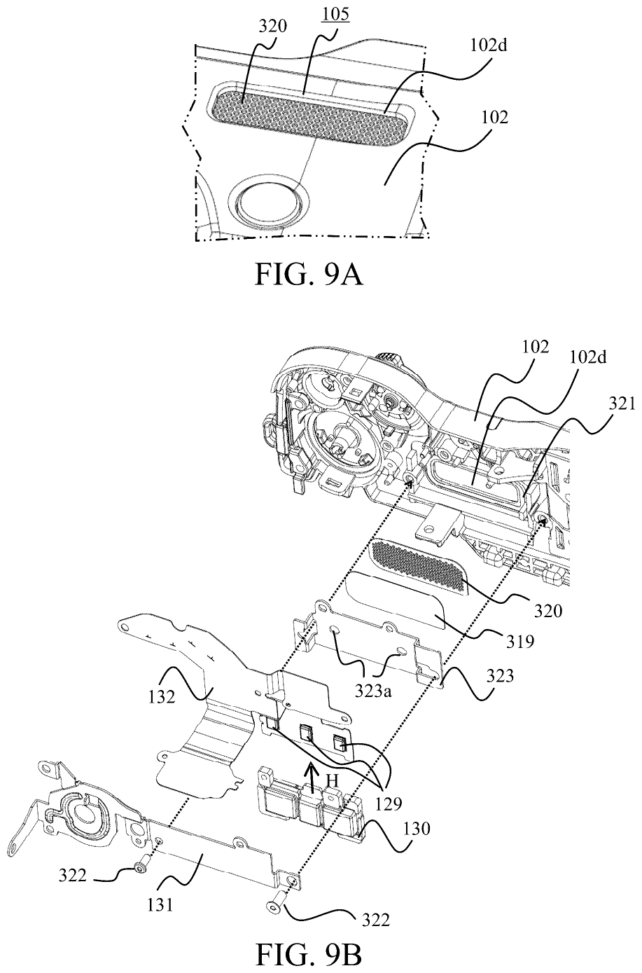

The structure of the microphone sound pickup unit 105 will be described below with reference to FIGS. 9A and 9B. FIGS. 9A and 9B are detailed perspective views of the microphone sound pickup unit 105. FIG. 9A is a detailed perspective view of the microphone sound pickup unit 105 when viewed from the exterior side of the digital camera 1. FIG. 9B is an exploded perspective view of the microphone sound pickup unit 105 when viewed from inside the digital camera 1.

The top cover 102 has an opening portion 102d for sound pickup. The opening portion 102d is blocked by a punching sheet 320 having continuously provided fine openings for sound pickup.

The punching sheet 320 is bonded to the top cover 102 by a double-sided adhesive tape 321. A mesh sheet 319 that is water-repellent to prevent intrusion of water from outside and breathable to allow sound to pass through is bonded to the back surface of the punching sheet 320. As described above with reference to FIG. 2, the microphone rubber 130 covers the microphone element 129, which is mounted on the FPC 132, by sandwiching it from the direction of arrow H. The microphone rubber 130 is placed with a surface having an unillustrated sound pickup hole in contact with a microphone forward holding member 323 and its opposite surface in contact with the holding member 131, and is fastened to the top cover 102 by a screw 322. The microphone forward holding member 323 is a component processed from a metal plate and provided with a sound pickup hole 323a to pick up sound for the microphone element 129.

Components constituting the microphone sound pickup unit 105 include the microphone element 129, the top cover 102, the double-sided adhesive tape 321, the punching sheet 320, the mesh sheet 319, the microphone forward holding member 323, the microphone rubber 130, the holding member 131, and the screw 322.

The copper plate 311 to which the fan 231 is fixed through the elastic member 305 will be referred to as a first component. The first component is not a component of the microphone sound pickup unit 105 and is configured not to contact any component of the microphone sound pickup unit 105. Thereby, vibration due to drive of the fan 231 can be prevented from being recorded as drive noise by the microphone sound pickup unit 105. A component to which the copper plate 311 as the first component is fixed will be referred to as a second component. The second component includes the duct 315, the heat sink 314, the heat-dissipating copper plate 312, and the screw 309, 310, and 316. The second component is a heat-dissipating unit that forms a heat-dissipating ventilation path. The second component is not a component of the microphone sound pickup unit 105 and is configured not to contact any component of the microphone sound pickup unit 105. To restrain vibration of the fan 231 from propagating to the top cover 102 as a component of the microphone sound pickup unit 105, the second component is not directly fixed to an exterior component contacting the top cover 102, such as the front cover 101. The second component is fixed to an internal component of the digital camera 1, such as the chassis 324, which does not constitute the microphone sound pickup unit 105.

As illustrated in FIG. 4, the gap G is formed between each of the fan 231, the elastic member 305, the first component, and the second component, and an exterior component contacting the microphone sound pickup unit 105, such as the front cover 101. The gap G is also formed between the fan 231 and an internal component of the digital camera 1 other than the elastic member 305. The gap G can restrain vibration of the fan 231 from being directly propagated to the microphone sound pickup unit 105 through the first and second components.

In this embodiment, the heat sink 314 is provided in the first air chamber 301 having the intake port 101a and heat generated by the heat sink 314 is dissipated to intake air, this embodiment is not limited to this example. The heat sink 314 may be provided in the second air chamber 318 having the exhaust ports 102a and 102b.

Although the rib 306b and the protrusion portions 306c are provided at the second wall portion 306 in this embodiment, ribs and protrusions may be provided at the first wall portion 304 on the first air chamber 301 side.

Although the intake side is the first air chamber 301 side and the exhaust side is the second air chamber 318 side in the present embodiment, the orientation of the fan 231 may be changed by 180 degrees so that exhaust air, which was guided in the rotational axis direction B, is instead guided in a direction opposite to the rotational axis direction B.

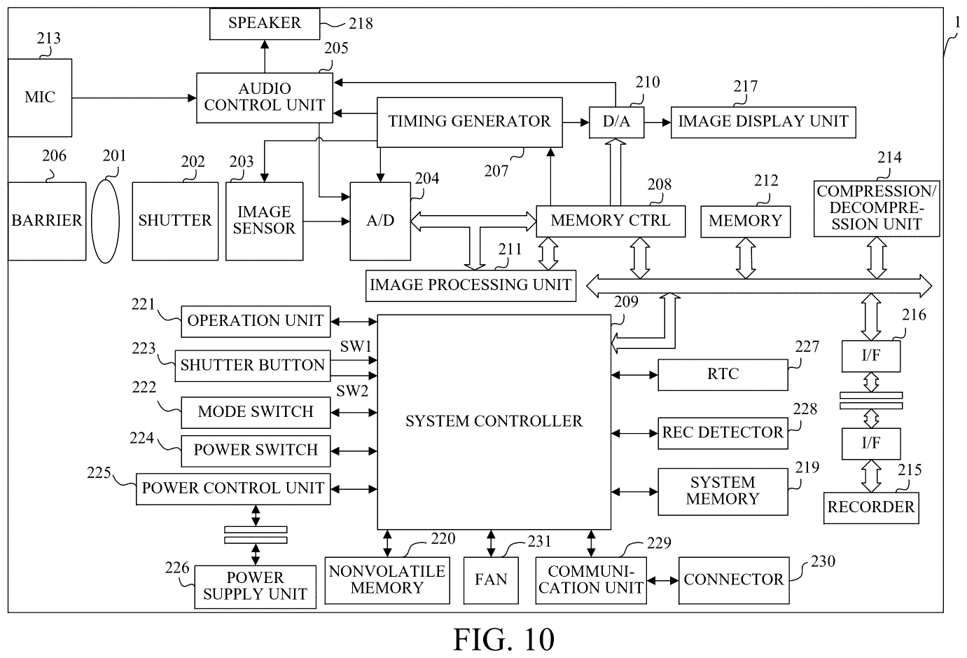

FIG. 10 is a block diagram illustrating the configuration of the digital camera 1. The digital camera 1 includes an imaging unit. The imaging unit includes an optical system, the image sensor 203, an A/D converter 204, a lens barrier 206, a timing generator 207, and the image processing unit 211.

The optical system includes an imaging lens 201 and a shutter 202 having an aperture function.

The image sensor 203 includes a CCD, a CMOS element, or the like that converts an optical image input through the optical system into an electric signal.

The A/D converter 204 is used to convert an analog signal output from the image sensor 203 into a digital signal and to convert an analog signal output from an audio control unit 205 into a digital signal.

The lens barrier 206 covers the imaging lens 201 and the image sensor 203 to reduce contamination and damage to them.

The timing generator 207 is controlled by a memory control unit 208 and the system controller 209 to supply clock signals and control signals to the image sensor 203, the audio control unit 205, the A/D converter 204, and a D/A converter 210.

The image processing unit 211 performs predetermined resize processing, such as pixel interpolation and reduction, and predetermined color conversion processing for data output from the A/D converter 204 and data stored in a memory 212. The image processing unit 211 also performs predetermined computation for captured image data, and the system controller 209 performs exposure control and focus detection control based on the computation result obtained. Thereby, Through-The-Lens (TTL) based autofocus (AF) processing, auto-exposure (AE) processing, and pre-flash emission (EF) processing are performed. Similarly, TTL based automatic white balance (AWB) processing is performed.

Data output from the A/D converter 204 is written into the memory 212 through the image processing unit 211 and the memory control unit 208 or through the memory control unit 208. The memory 212 also stores audio data recorded by the microphone sound pickup unit 105, captured still and moving images, and information associated with images, such as file headers when image files are formed. The memory 212 has a storage capacity sufficient to store a predetermined number of still images, and moving images and audio for a predetermined duration.

A compression/decompression unit 214 compresses and decompresses image data by adaptive discrete cosine transform (ADCT) or the like. More specifically, the compression/decompression unit 214 reads a captured image stored in the memory 212 according to a trigger from the shutter 202, performs compression processing, and writes the processed data to the memory 212. The compression/decompression unit 214 also reads a compressed image that is read into the memory 212 from a recorder (memory) 215 or the like, performs decompression processing, and writes the processed data into the memory 212. The image data written to the memory 212 by the compression/decompression unit 214 is converted into a file by a file processing unit of the system controller 209 and recorded onto a recording medium in the recorder 215 through a recording medium interface (I/F) 216.

The memory 212 also functions as an image display memory, and display image data written to the memory 212 is displayed by an image display unit 217 through the D/A converter 210.

An audio signal output from a microphone 213 is converted into a digital signal by the A/D converter 204 through the audio control unit 205 constituted by an amplifier or the like, and then is stored in the memory 212 by the memory control unit 208.

Audio data recorded in the recorder 215 is read into the memory 212, processed by the audio control unit 205 through the D/A converter 210, and then output as sound by a speaker 218.

The system controller (control unit) 209 controls the entire digital camera 1. A system memory 219 stores constants, variables, computer programs, and the like for operation of the system controller 209.

A nonvolatile memory 220 is an electrically erasable and recordable memory and may be, for example, an EEPROM.

A shutter switch (SW1), a shutter switch (SW2), and an operation unit 221 are used by a user inputting a variety of operation instructions into the system controller 209.

A mode switch 222 is used to switch the operation mode of the system controller 209 to a still image capturing mode, a continuous image capturing (continuous shooting) mode, a moving image capturing mode, a playback mode, or the like.

The shutter switch (SW1) is turned on when a shutter button 223 provided on the digital camera 1 is operated halfway (half-pressed). When the shutter switch (SW1) is turned on, operation start of autofocus (AF) processing, auto-exposure (AE) processing, automatic white balance (AWB) processing, pre-flash emission (EF) processing, and the like is instructed.

The shutter switch (SW2) is turned on when the shutter button 223 is completely operated (fully pressed). When the shutter switch (SW2) is turned on, operation start of a series of imaging processing from signal reading from the image sensor 203 to image data writing into the recorder 215 is instructed.

The operation unit 221 includes a variety of buttons, a touch panel, and the like. More specifically, the operation unit 221 includes a delete button, a menu button, a setting button, and a four-way key disposed in a cross shape.

When the menu button is pressed, a menu screen on which various kinds of setting can be performed is displayed on the image display unit 217. The user can intuitively perform various kinds of setting by using the menu screen displayed on the image display unit 217, the four-way key, and the setting button. Moreover, contact of a user's finger or a pen on the image display unit 217 may be detected, and an icon displayed on the image display unit 217 may be recognized in the same manner as an operation of a switch or dial, such as a button or dial. Furthermore, an operation similar to that of a bidirectional key may be performed by using an operation member such as a jog dial, rotation of which can be detected.

A power button 224 is used to switch between power-on and power-off.

A power control unit 225 includes a battery detection circuit, a DC-DC converter, a switch circuit for switching blocks to be energized, and the like and detects existence of a mounted battery, the kind of the battery, and the battery remaining amount. In addition, the power control unit 225 controls the DC-DC converter based on the detection result and an instruction from the system controller 209 and supplies the necessary voltage to each component including the recorder 215 for a necessary duration.

A power supply unit 226 includes a primary battery such as an alkaline battery or a lithium battery, a secondary battery such as a NiCd battery, a NiMH battery, or a Li-ion battery, an AC adapter, or the like.

The power supply unit 226 and the power control unit 225 are connected through a camera-side power-source connector.

A real-time clock (RTC) 227 includes an internal power supply unit separate from the power control unit 225 and continues timekeeping even when the power supply unit 226 is turned off.

The system controller 209 performs timer control by using date and time acquired from the RTC 227 at activation.

A recording medium attachment/detachment detector (REC detector) 228 detects whether a recording medium is attached to a recording medium slot in the recorder 215.

A communication unit 229 performs various communication processes such as RS232C, USB, IEEE1394, P1284, SCSI, modem, LAN, and wireless communication.

A communication connector 230 (antenna in a case of wireless communication) connects the digital camera 1 to another instrument through the communication unit 229.

The fan 231 is controlled to drive (rotation/stop and rotational speed) by the system controller 209.

While the disclosure has described example embodiments, it is to be understood that the disclosure is not limited to the example embodiments. The scope of the following claims is to be accorded the broadest interpretation so as to encompass all such modifications and equivalent structures and functions.

This embodiment can provide an image pickup apparatus that has a reduced size and suppresses propagation of vibration to fan attachment components and generation of vibration noise during fan driving.

This application claims priority to Japanese Patent Application No. 2024-094454, which was filed on Jun. 11, 2024, and which is hereby incorporated by reference herein in its entirety.

What is claimed is:

1. An image pickup apparatus comprising:
a sound pickup unit configured to pick up sound during moving image capturing;
a fan;
an elastic member provided in contact with the fan; and
a first component that fixes the fan through the elastic member,
wherein the first component does not contact the sound pickup unit.

2. The image pickup apparatus according to claim 1, further comprising a second component that fixes the first component,
wherein the second component does not contact the sound pickup unit.

3. The image pickup apparatus according to claim 2, wherein the second component dissipates heat by using airflow generated by the fan, and
wherein the first component and the second component form part of a flow path of the airflow.

4. The image pickup apparatus according to claim 2, further comprising:
a first exterior member that holds the sound pickup unit; and
a second exterior member provided in contact with the first exterior member,
wherein the fan, the elastic member, the first component, and the second component do not contact the first exterior member nor the second exterior member.

5. The image pickup apparatus according to claim 1, wherein the elastic member has an opening portion configured to serve as a vent for airflow generated by the fan.

6. The image pickup apparatus according to claim 1, wherein the sound pickup unit includes a microphone and a component having an opening configured to guide sound to the microphone.

7. The image pickup apparatus according to claim 1, wherein the fan includes a movable portion and a fixed portion rotatably supporting the movable portion and having a plurality of surfaces, and
wherein only one of the plurality of surfaces is fixed inside the image pickup apparatus.

8. The image pickup apparatus according to claim 1, wherein the fan is fixed to the first component by bonding through the elastic member.

9. The image pickup apparatus according to claim 1, further comprising:
an imaging unit; and
an accessory shoe for mounting an external accessory,
wherein the accessory shoe, the sound pickup unit, and the fan are disposed on a top surface of the imaging unit and arranged in a direction orthogonal to an optical axis, and
wherein the accessory shoe is disposed between the sound pickup unit and the fan.

10. The image pickup apparatus according to claim 9, further comprising an operation member disposed on a top surface of the image pickup apparatus,
wherein the fan is disposed on a surface opposite to the operation member via the accessory shoe.

11. The image pickup apparatus according to claim 1, wherein the fan exhausts air in a direction in which the sound pickup unit is not disposed.

12. The image pickup apparatus according to claim 10, further comprising:
a first holding member that fixes the sound pickup unit; and
a second holding member that fixes the operation member that is operated during moving image capturing,
wherein the first holding member and the second holding member are separate components.

13. The image pickup apparatus according to claim 1, further comprising a windbreak unit disposed in a direction different from a direction in which the fan exhausts air.

14. The image pickup apparatus according to claim 1, further comprising at least one processor that executes instructions to control the image pickup apparatus.

15. The image pickup apparatus according to claim 1, further comprising a memory configured to store audio data acquired by the sound pickup unit.
